(19) United States
(12) Patent Application Publication
(10) Pub. No.: US 2012/0008364 A1
(43) Pub. Date: Jan. 12, 2012

(54) ONE TIME PROGRAMMABLE MEMORY AND THE MANUFACTURING METHOD AND OPERATION METHOD THEREOF

(75) Inventors: Tung-Ming Lai, Taipei County (TW); Teng-Feng Wang, Hsinchu City (TW); Kai-An Hsueh, Miaoli County (TW)

(73) Assignee: MAXCHIP ELECTRONICS CORP., Hsinchu City (TW)

(21) Appl. No.: 12/916,643

(22) Filed: Nov. 1, 2010

(30) Foreign Application Priority Data
Jul. 6, 2010 (TW) 99122174

(51) Int. Cl. G11C 17/12; H01L 21/336; H01L 27/118

(52) U.S. Cl. 365/103; 257/202; 438/197; 257/E21.409; 257/E27.105

(57) ABSTRACT

A one time programmable memory having a memory cell formed on a substrate is provided. The memory cell has a transistor and an anti-fuse structure. The anti-fuse structure is consisted of a doping region, and a dielectric layer and a conductive layer is formed in the top edge corner region of an isolation structure. The upper surface of the isolation structure is lower than the surface of the substrate so as to expose the top edge corner region. The conductive layer is formed on the isolation structure and covers the top edge corner region. The dielectric layer is formed on the top edge corner region and between the doping region and the conductive layer. The memory cell stores the digital data depending on whether the dielectric layer breaks down or not.

### CROSS-REFERENCE TO RELATED APPLICATION

This application claims the priority benefit of Taiwan application serial no. 99122174, filed on Jul. 6, 2010. The entirety of the above-mentioned patent application is hereby incorporated by reference herein and made a part of this specification.

### BACKGROUND OF THE INVENTION

1. Field of the Invention

The invention relates to a semiconductor memory device and an operation method thereof More particularly, the invention relates to a one time programmable memory and an operation method thereof.

2. Description of Related Art

With its advantage of safeguarding the written data even after it is not powered, the non-volatile memory device has become a memory device widely used in personal computers and electronic equipments.

Generally, memories can be simply classified into two types: read only memory (ROM) and random access memory (RAM) according to the difference in reading/writing functions. The read only memory (ROM) can be further categorized into erasable programmable read only memory (EPROM), electrically erasable programmable read only memory (EEPROM), mask read only memory (mask ROM) and one time programmable read only memory (OTPROM).

Although EPROM and EEPROM have both a write-in and an erase function, and hence a wider range of actual applications, these memories also have a more complicated fabrication process and a higher production cost.

On the other hand, although a mask ROM is simple and inexpensive to fabricate, a photomask is required to define the write-in data. Hence, the mask ROM has some limitations in real applications.

For OTPROM, data can be written into the memory after leaving the factory. In other words, the operating environment of the memory can be programmed through a write-in operation carried out by the users in their premises. Thus, OTPROM is more convenient to use compared with the mask ROM.

As techniques for manufacturing deep sub-micron semiconductors start to mature, physical dimensions of devices are reduced little by little. Hence, the size of memory cells in memory devices has become smaller and smaller. In another aspect, since information electronic products including computers, mobile phones, digital cameras, and personal digital assistants (PDAs) are required to process and store an increasing amount of data, memory capacity required by these information electronic products is increased accordingly. In order to satisfy said formidable demand for the memory devices with compactness and large memory volume, producing small-sized and highly-integrated memory devices featuring fine quality is one of the common goals to be achieved by this industry.

In light of the foregoing aspects, a miniaturized, simplified, and low-cost OTPROM needs to be developed.

### SUMMARY OF THE INVENTION

Accordingly, the invention is directed to a one time programmable memory having miniaturized devices by disposing an anti-fuse structure (constituted by a doped region, a dielectric layer, and a conductive layer) on a top edge corner region of the isolation structure.

The invention is directed to a manufacturing method of a one time programmable memory. The manufacturing method utilizes a conventional CMOS process, such that devices have higher integration, and the manufacturing cost thereof is also reduced effectively.

The invention is directed to an operation method of a one time programmable memory. During the programming process, whether the dielectric layer breaks down or not can be utilized to provide a memory cell with a one time writing characteristic. Moreover, the stored data is non-volatile. During the reading process, a voltage change of a bit line resulted from whether the dielectric layer breaks down or not is utilized to interpret digital data.

The invention is directed to a one time programmable memory having a memory cell disposed on a substrate. The memory cell includes a gate, a gate dielectric layer, a first doped region and a second doped region, an isolation structure, a conductive layer, and a dielectric layer. The gate is disposed on the substrate. The gate dielectric layer is disposed between the substrate and the gate. The first doped region and the second doped region are disposed in the substrate at opposite sides of the gate respectively. The isolation structure is disposed in the substrate and adjacent to the first doped region. Here, an upper surface of the isolation structure is lower than a surface of the substrate so as to expose a top edge corner region. The conductive layer is disposed on the isolation structure and covers the top edge corner region. The dielectric layer is disposed in the top edge corner region and located between the conductive layer and the first doped region. The memory cell stores digital data depending on whether the dielectric layer breaks down or not.

In an embodiment of the invention, the first doped region is a drain region and the conductive layer is electrically connected to a bit line; and the second doped region is a source region and electrically connected to a source line.

In an embodiment of the invention, the first doped region is a source region and the conductive layer is electrically connected to a source line; and the second doped region is a drain region and electrically connected to a bit line.

In an embodiment of the invention, the first doped region includes a third doped region and a fourth doped region. The third doped region is disposed between the isolation structure and the fourth doped region and located below the conductive layer.

In an embodiment of the invention, the one time programmable memory further includes a plurality of memory cells, a plurality of word lines, a plurality of source lines and a plurality of bit lines. The memory cells are arranged in a column/row to form an array, and two adjacent memory cells are disposed in mirror symmetry manner in a column direction. The word lines are each connected to the gate of the memory cells in the same row respectively. The source lines are connected to the second doped region of the memory cells in the same row respectively. The bit lines are connected to the conductive layer of the memory cells in the same column respectively.

In an embodiment of the invention, the one time programmable memory further includes a plurality of memory cells, a plurality of word lines, a plurality of source lines and a plurality of bit lines. The memory cells are arranged in a column/row to form an array, and two adjacent memory cells are disposed in mirror symmetry manner in a column direction. The word lines are each connected to the gates of the memory cells in the same row respectively. The source lines are connected to the conductive layer of the memory cells in the same row respectively. The bit lines are connected to the second doped region of the memory cells in the same column respectively.

The invention is directed to a manufacturing method of a one time programmable memory. The manufacturing method includes the following steps: providing a substrate having an isolation structure formed therein; forming a first dielectric layer on the substrate; removing a portion of the first dielectric layer and a portion of the isolation structure, such that an upper surface of the isolation structure is lower than a surface of the substrate so as to expose a top edge corner region; forming a second dielectric layer in the top edge corner region; forming a gate and a conductive layer on the substrate, wherein the conductive layer is disposed on the isolation structure and covers the top edge corner region; forming a first doped region and a second doped region in the substrate at opposite sides of the gate, wherein the first doped region, the second dielectric layer, and the conductive layer constitute a fuse-structure.

In an embodiment of the invention, the second dielectric layer is formed using a thermal oxidation.

In an embodiment of the invention, before the step of removing a portion of the first dielectric layer and a portion of the isolation structure, the method further includes forming a third doped region in the top edge corner region.

In an embodiment of the invention, a method of forming the gate and the conductive layer on the substrate includes forming a conductive material layer on the substrate and patterning the conductive material layer.

The invention is directed to an operation method of a one time programmable memory. The one time programmable memory at least includes: a plurality of memory cells arranged in a column/row to form an array, where two adjacent memory cells are disposed in mirror symmetry manner in a column direction, each memory cell including: a transistor having a first doped region and a second doped region, an isolation structure adjacent to the first doped region and exposing a top edge corner region, a conductive layer disposed on the isolation structure and covering the top edge corner region, and a dielectric layer disposed in the top edge corner region and located between the conductive layer and the first doped region; a plurality of word lines, each connected to the gates of the memory cells in the same row respectively; a plurality of source lines, each connected to the conductive layer of the memory cells in the same row respectively; and a plurality of bit lines, each connected to the second doped region of the memory cells in the same column respectively. The operation method of the one time programmable memory includes when performing a programming operation, applying a first voltage to a selected word line coupled to a selected memory cell, applying a second voltage to a selected source line coupled to the selected memory cell, applying a third voltage to a selected bit line coupled to the selected memory cell or floating the selected bit line. The first voltage is sufficient to turn on a channel of the transistor of the selected memory cell, and a voltage difference between the second voltage and the third voltage is sufficient for the dielectric layer to break down.

In an embodiment of the invention, the first voltage is 3.3 Volts (V) and the voltage difference is 6-9 V. The second voltage is 6-9 V. The third voltage is 0 V.

In an embodiment of the invention, the operation method of the one time programmable memory further includes when performing the programming operation, applying a fourth voltage to other unselected bit lines. Herein, a voltage difference between the second voltage and the fourth voltage is not sufficient for the dielectric layer to break down.

In an embodiment of the invention, the fourth voltage is 6-9 V.

In an embodiment of the invention, the operation method of the one time programmable memory further includes when performing a reading operation, applying a fifth voltage to the selected word line coupled to the selected memory cell, so that the selected source line coupled to the selected memory cell is grounded, applying a sixth voltage to the selected bit line coupled to the selected memory cell to read the selected memory cell. Here, the fifth voltage is sufficient to turn on the channel of the transistor of the selected memory cell.

In an embodiment of the invention, the fifth voltage is 3.3 V and the sixth voltage is 1-4 V.

The invention is directed to an operation method of a one time programmable memory. The one time programmable memory at least includes: a plurality of memory cells arranged in a column/row to form an array, where two adjacent memory cells are disposed in mirror symmetry manner in a column direction, each memory cell including: a transistor having a first doped region and a second doped region, an isolation structure adjacent to the first doped region and exposing a top edge corner region, a conductive layer disposed on the isolation structure and covering the top edge corner region, and a dielectric layer disposed in the top edge corner region and located between the conductive layer and the first doped region; a plurality of word lines, each connected to the gate of the memory cells in the same row respectively; a plurality of source lines, each connected to the second doped region of the memory cells in the same row respectively; and a plurality of bit lines, each connected to the conductive layer of the memory cells in the same column respectively. The operation method of the one time programmable memory includes when performing a programming operation, applying a first voltage to a selected word line coupled to a selected memory cell, applying a second voltage to a selected bit line coupled to the selected memory cell, applying a third voltage to a selected source line coupled to the selected memory cell or floating the selected source line. The first voltage is sufficient to turn on a channel of the transistor of the selected memory cell, and a voltage difference between the second voltage and the third voltage is sufficient for the dielectric layer to break down.

In an embodiment of the invention, the first voltage is 3.3 V. The voltage difference is 6-9 V. The second voltage is 6-9 V. The third voltage is 0 V.

In an embodiment of the invention, the operation method of the one time programmable memory further includes when performing a reading operation, applying a fourth voltage to the selected word line coupled to the selected memory cell, so that the selected source line coupled to the selected memory cell is grounded, applying a fifth voltage to the selected bit line coupled to the selected memory cell to read the selected memory cell. Here, the fourth voltage is sufficient to turn on the channel of the transistor of the selected memory cell.

In an embodiment of the invention, the fourth voltage is 3.3 V. The third voltage is 1-4 V.

In light of the foregoing, since the one time programmable memory of the invention have an anti-fuse structure, which is constituted by the doped region, the dielectric layer, and the conductive layer, the size of devices on the top edge corner region of the isolation structure can be reduced. Moreover, by disposing the anti-fuse structure in the top edge corner region, the dielectric layer breaks down easily so as to reduce the operation voltage.

During the programming process of the operation method of the one time programmable memory in the invention, whether the dielectric layer breaks down or not is utilized to provide the memory cell with a one time writing characteristic. During the reading process, the voltage change of a bit line resulted from whether the dielectric layer breaks down or not is utilized to interpret digital data.

The manufacturing method of the one time programmable memory in the invention utilizes a conventional CMOS process, such that devices have higher integration and the manufacturing cost thereof is reduced effectively.

To make the above and other features and advantages of the present invention more comprehensible, several embodiments accompanied with figures are detailed as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows an equivalent circuit diagram of a one time programmable memory according to one embodiment of the invention.

FIG. 2 is a cross-sectional view showing a structure of a one time programmable memory cell according to one embodiment of the invention.

FIG. 3A is a schematic diagram showing a programming operation of a memory array according to one embodiment of the invention.

FIG. 3B is a schematic diagram showing a reading operation of a memory array according to one embodiment of the invention.

FIG. 4 shows an equivalent circuit diagram of a one time programmable memory according to another embodiment of the invention.

FIG. 5A is a schematic diagram showing a programming operation of a memory array according to one embodiment of the invention.

FIG. 5B is a schematic diagram showing a reading operation of a memory array according to one embodiment of the invention.

FIGS. 6A through 6E are schematic cross-sectional views showing the flowchart for fabricating a one time programmable memory of the invention.

### DESCRIPTION OF EMBODIMENTS

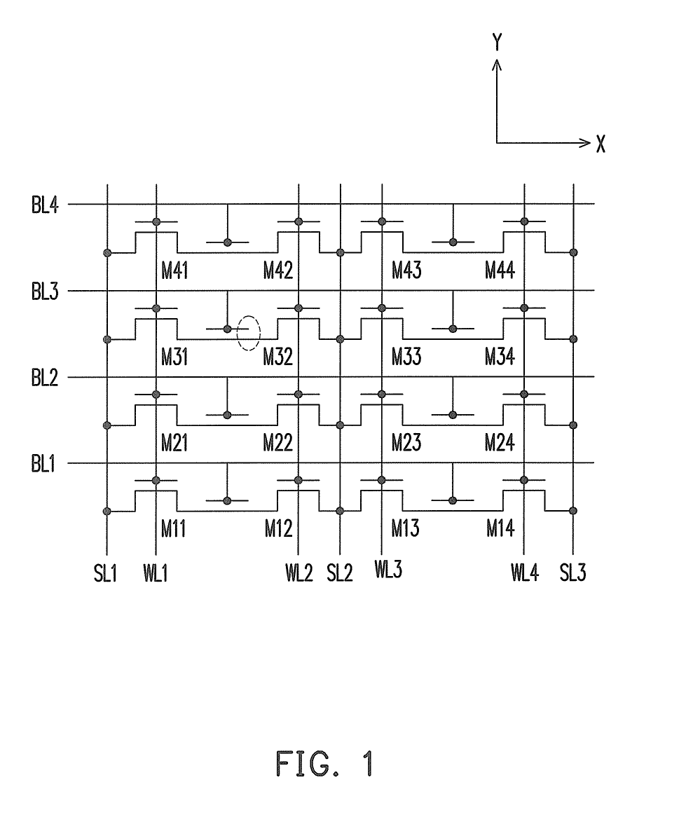

FIG. 1 shows an equivalent circuit diagram of a one time programmable memory of the invention.

Referring to FIG. 1, the one time programmable memory of the invention is constituted by a plurality of memory cells, for example. A memory cell array is illustrated in the following. In the present embodiment, a memory cell array constituted by 4*4 memory cells is used as an example. However, the number of memory cells constituting the memory cell array depends on actual demands, and the memory cell array can be constituted by 64, 256, or 512 memory cells, for instance. In FIG. 1, an X direction is defined as a column direction and a Y direction is defined as a row direction.

The memory cell array includes a plurality of memory cells M11-M44, a plurality of word lines WL1-WL4, a plurality of source lines SL1-SL3, and a plurality of bit lines BL1-BL4.

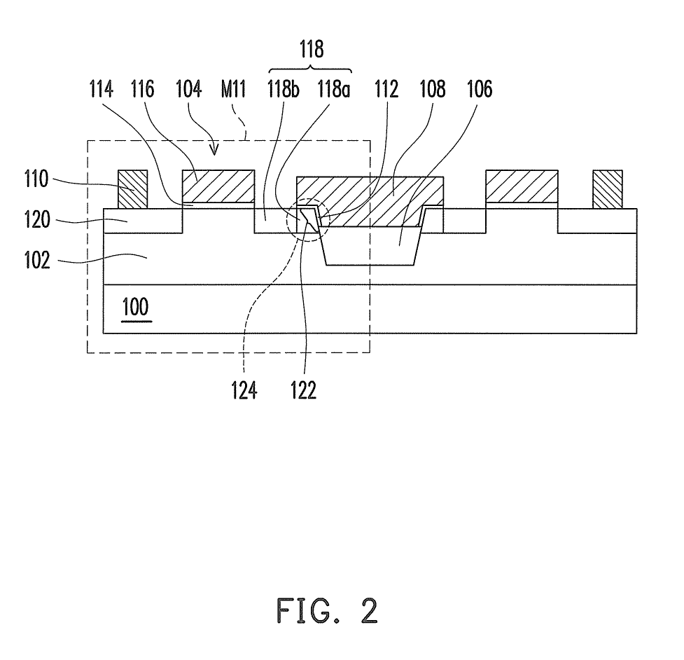

Firstly, the structure of the memory cell is described. FIG. 2 is a cross-sectional view showing a structure of a one time programmable memory cell of the invention. In FIG. 2, a memory cell M11 is used as an example to further illustrate in details.

Referring to FIG. 2, the memory cell M11 is constituted by a substrate 100, a P-type well 102, a transistor 104, an isolation structure 106, a conductive layer 108, a conductive layer 110, and a dielectric layer 112.

The substrate 100 is, for example, a silicon substrate, and the P-type well 102 is disposed in the substrate 100.

The transistor 104 is disposed in an active region of the substrate 100. The transistor 104 is, for example, constituted by a gate dielectric layer 114, a gate 116, a doped region 118, and a doped region 120.

The gate 116 is disposed on the substrate 100 and fabricated using doped polysilicon, for example. The gate 112 serves as the word line of the memory cell. The gate dielectric layer 114 is set between the gate 116 and the substrate 100. The gate dielectric layer 114 is fabricated using silicon oxide, for example. The doped region 118 and the doped region 120 are disposed in the substrate 100 on two opposite sides of the gate 116 respectively. The doped region 118 and the doped region 120 are N-doped regions, for example. The doped region 118 is formed, for example, by a doped region 118a and a doped region 118b. The doped region 118 is disposed between the isolation structure 106 and the doped region 118b, and located under the conductive layer 110.

The isolation structure 106 is disposed in the substrate 100 to define the active region. The isolation structure 106 is shallow trench isolation structure, for example. The isolation structure 106 is adjacent to the doped region 118. Here, an upper surface of the isolation structure 106 is lower than a surface of the substrate 100 so as to expose a top edge corner region 122.

The conductive layer 108 is disposed on the doped region 120. The conductive layer 110 is disposed on the isolation structure 106 and covers the top edge corner region 122.

The dielectric layer 112 is disposed in the top edge corner region 122 and located between the conductive layer 110 and the doped region 118. Here, an anti-fuse structure 124 constituted by the doped region 118, the dielectric layer 112, and the conductive layer 110 is disposed on the top edge corner region 112 of the isolation structure 106. The memory cell 100 stores digital data by determining whether the dielectric layer 112 breaks down or not. Accordingly, the memory cell is non-volatile. Since the anti-fuse structure 124 is disposed in the top edge corner region 122, electric charges can easily concentrate around the top edge corner region 122 to produce an electric discharge that breaks down the dielectric layer 112. Thus, the voltage for operating the dielectric layer 112 is reduced. The dielectric layer 112 is fabricated using silicon oxide, for example, and preferably has a thickness ranging from 26 Å to 46 Å. Obviously, the dielectric layer 112 can also be fabricated using other dielectric materials having a thickness equivalent to the silicon oxide having a thickness ranging from 26 Å to 46 Å. Through the selection of a suitable dielectric material and the formation of a dielectric layer with appropriate thickness, the breakdown voltage and device performance of the memory can be controlled.

A plurality of memory cells M11-M45 are serially connected in the column direction to form a memory cell column. For instance, the memory cells M11-M14 are serially connected into a memory cell column; the memory cells M21-M24 are serially connected into a memory cell column; the memory cells M31-M34 are serially connected into a memory cell column; the memory cells M41-M44 are serially connected into a memory cell column. In the column direction, two adjacent memory cells are disposed in mirror symmetry manner. Moreover, two adjacent memory cells share the conductive layer 110 (referring to FIG. 2) or the doped region 120 (referring to FIG. 2).

In the present embodiment, the doped region 118 is a drain region, for example, and the conductive layer 110 is electrically connected to a bit line, for instance; the doped region 120 is a source region, for example, and electrically connected to a source line.

The word lines WL1-WL4 are arranged in parallel on the substrate and extend in the row direction (Y direction). Each of the word lines WL1-WL4 is connected to the gate of the memory cells in the same row respectively. For instance, the word line WL1 is connected to the gate of the memory cells M11-M41; the word line WL2 is connected to the gate of the memory cells M12-M42; the word line WL3 is connected to the gate of the memory cells M13-M43; the word line WL4 is connected to a control gate of the memory cells M14-M44.

The source lines SL1-SL3 are arranged in parallel on the substrate and extend in the row direction (Y direction). Each of the source lines SL1-SL3 is connected to the source region of the memory cells in the same row respectively. For instance, the source line SL1 is connected to the source region of the memory cells M11-M41; the source line SL2 is connected to the source region of the memory cells M12-M42 and the memory cells M13-M43; the source line SL4 is connected to the source region of the memory cells M14-M44.

The bit lines BL1-BL3 are arranged in parallel on the substrate and extend in the column direction (X direction). Each of the bit lines BL1-BL3 is connected to the conductive layer of the memory cells in the same column respectively. For instance, the bit line BL1 is connected to the conductive layer of the memory cells M11-M41; the bit line BL2 is connected to the conductive layer of the memory cells M12-M42; the bit line BL3 is connected to the conductive layer of the memory cells M13-M43; the bit line BL4 is connected to conductive layer of the memory cells M14-M44.

The one time programmable memory of the invention has the anti-fuse structure 124 disposed on the top edge corner region 122 of the isolation structure 106. The anti-fuse structure 124 is constituted by the doped region 118, the dielectric layer 112, and the conductive layer 110. Whether the conductive layer 110 (bit line/source line) and the conductive layer 108 (source line/bit line) are conducted is determined through whether the dielectric layer 112 breaks down or not. Consequently, digital data is stored and the memory cell is non-volatile.

In addition, the anti-fuse structure 124 is disposed in the top edge corner region 122. Thus, electric charges can easily concentrate around the top edge corner region 122 to produce an electric discharge that breaks down the dielectric layer 112. Thus, the voltage for operating the dielectric layer 112 is reduced.

The breakdown voltage and device performance of the memory can be controlled through a proper selection of the material and thickness of the dielectric layer 112.

Next, the operation method of the one time programmable memory of the invention including operation modes such as programming and reading is explained. One embodiment is provided to illustrate the operation method of the one time programmable memory of the invention. However, the operation method of the non-volatile memory array of the invention is not limited to these operations. The memory cell M32 shown in the figure is taken as an example in the following description.

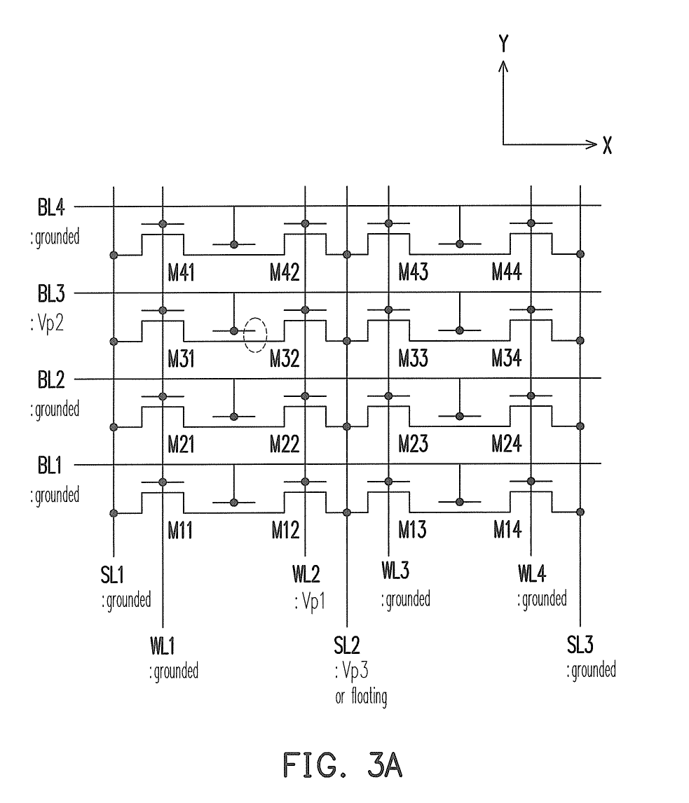

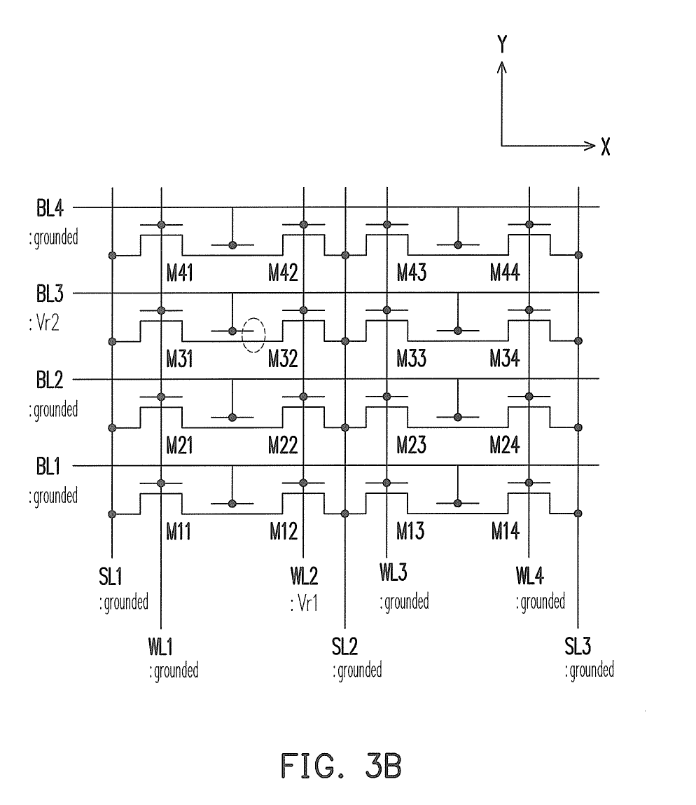

FIG. 3A is a schematic diagram showing a programming operation of a memory array according to one embodiment of the invention.

Referring to FIG. 3A, when a programming operation is performed to the selected memory cell M32, a voltage Vp1 is applied to the selected word line WL2 coupled to the selected memory cell M32, a voltage Vp2 is applied to the selected bit line BL3 coupled to the selected memory cell M32, a voltage Vp3 is applied to the selected source line SL2 coupled to the selected memory cell M32 or the selected source line SL2 is floating. The voltage Vp1 is sufficient to turn on a channel of the transistor of the selected memory cell. The voltage Vp1 is, for instance, 3.3 V. A voltage difference between the voltage Vp2 and the voltage Vp3 is sufficient for the dielectric layer 112 to break down. The voltage difference is 6-9 V, for example. The voltage Vp2 is 6-9 V, for instance, while the voltage Vp3 is, for example, 0 V.

Moreover, other unselected word lines WL1, WL3, WL4, other unselected bit lines BL1, BL2, BL4, and other unselected source lines SL1, SL3 are grounded.

As shown in FIG. 3A, when the selected memory cell M32 is being programmed, the 3.3 V voltage applied to the selected word line WL2 turns on the channel of the transistor, such that the 0 V voltage applied to the selected source line SL2 is conducted to the drain region, and the voltage of the drain region is maintained at about 0 V. At this point, a 6-9 V voltage is applied to the selected bit line BL3. Therefore, a large voltage difference is generated between the selected bit line BL3 and the drain region. As a result, the dielectric layer breaks down and the memory cell M32 is programmed.

As for other unselected memory cells M12, M22, M42 sharing the word line WL2 and the source line SL2 with the selected memory cell M32, when the programming operation is performed, since the unselected bit lines BL1, BL2, BL4 coupled to these unselected memory cells M12, M22, M42 are grounded, the unselected bit lines BL1, BL2, BL4 and the drain region have no voltage difference. Thus, the unselected memory cells M12, M22, M42 are not programmed.

As for other unselected memory cells M31, M33, M34 sharing the bit line BL3 with the selected memory cell M32, when the programming operation is performed, since the unselected word line WL1, WL3, WL4 coupled to these unselected memory cells M31, M33, M34 are grounded, the selected bit line BL3 and the drain region have no voltage difference. Therefore, the unselected memory cells M31, M33, M34 are not programmed.

Although the above-mentioned programming operation of the one time programmable memory is performed on a single memory cell in the memory array, the programming operation of the non-volatile memory of the invention can also be coded in units of byte, sector or block by controlling the various word lines and bit lines.

FIG. 3B is a schematic diagram showing a reading operation of a memory array according to one embodiment of the invention.

When the reading operation is performed, a voltage Vr1 is applied to the selected word line WL2 coupled to the selected memory cell M32, so that the selected source line SL2 coupled to the selected memory cell M32 is grounded. Also, a voltage Vr2 is applied to the selected bit line BL3 coupled to the selected memory cell M32 to read the selected memory cell M32. The voltage Vr1 is sufficient to turn on the channel of the transistor of the selected memory cell M32. The voltage Vr1 is, for example, 3.3 V. The voltage Vr2 is, for example, 1-4 V.

Then, a 3.3 V voltage, for example, is applied to the word line WL2 to turn on the channel of the transistor. When the dielectric layer breaks down, the transistor and the bit line BL3 are conducted, electrons are channeled away through the source line SL2. The voltage on the bit line BL3 is thus reduced. When the dielectric layer does not break down, the transistor and the electrode are not conducted; consequently, the electrons are not channeled away through the source line SL2. The voltage on the bit line BL3 is thus maintained at about 1-4V. As a result, whether the digital data stored inside the memory cell is ‘1’ or ‘0’ can be determined by reading the voltage on the bit line.

In the operation mode of the one time programmable memory in the invention, digital data is determined according to whether the bit line and the source line are conducted, which is in turn determined by whether the dielectric layer breaks down or not.

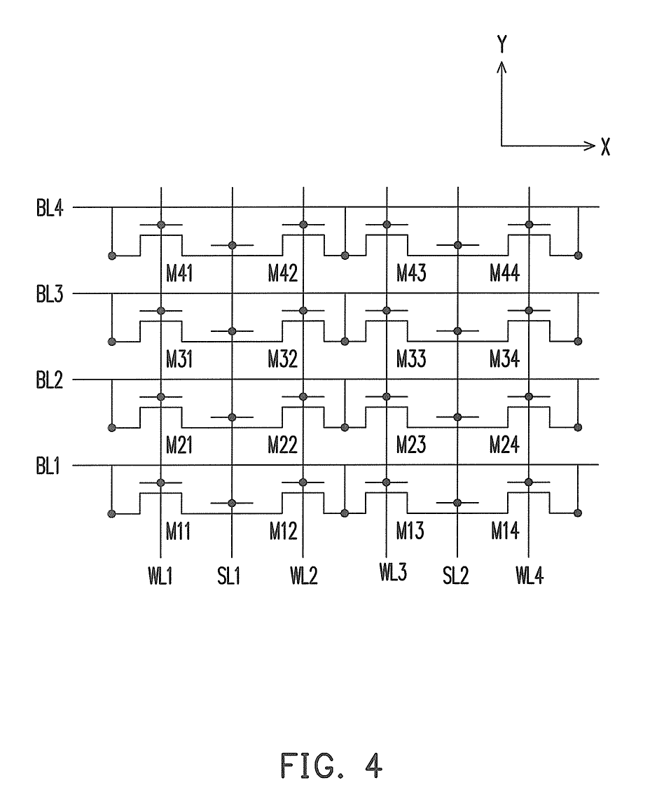

FIG. 4 shows an equivalent circuit diagram of a one time programmable memory according to another embodiment of the invention.

The one time programmable memory shown in FIG. 4 is different from the one time programmable memory depicted in FIG. 1 in that the doped region 118 illustrated in FIG. 2 is a source region and the doped region 110 is electrically connected to the source line; the doped region 120 is a drain region and electrically connected to the bit line.

The word lines WL1-WL4 are arranged in parallel on the substrate and extend in the row direction (Y direction). Each of the word lines is connected to the gate of the memory cells in the same row respectively. For instance, the word line WL1 is connected to the gate of the memory cells M11-M41; the word line WL2 is connected to the gate of the memory cells M12-M42; the word line WL3 is connected to the gate of the memory cells M13-M43; the word line WL4 is connected to a control gate of the memory cells M14-M44.

The source lines SL1-SL3 are arranged in parallel on the substrate and extend in the row direction (Y direction). Each of the source lines SL1-SL3 is connected to the conductive layer of the memory cells in the same row respectively. For instance, the source line SL1 is connected to the conductive layer of the memory cells M11-M41 and the memory cells M12-M42; the source lines SL2 is connected to the conductive layer of the memory cells M13-M43 and the memory cells M14-M44.

The bit lines BL1-BL3 are arranged in parallel on the substrate and extend in the column direction (X direction). Each of the bit lines BL1-BL3 is connected to the drain region of the memory cells in the same column respectively. For instance, the bit line BL1 is connected to the drain region of the memory cells M11-M14; the bit line BL2 is connected to the drain region of the memory cells M21-M24; the bit line BL3 is connected to the drain region of the memory cells M31-M34; the bit line BL4 is connected to drain region of the memory cells M41-M44.

Next, the operation method of the one time programmable memory of the invention including operation modes such as programming and reading is explained. The memory cell M32 shown in the figure is taken as an example in the following description.

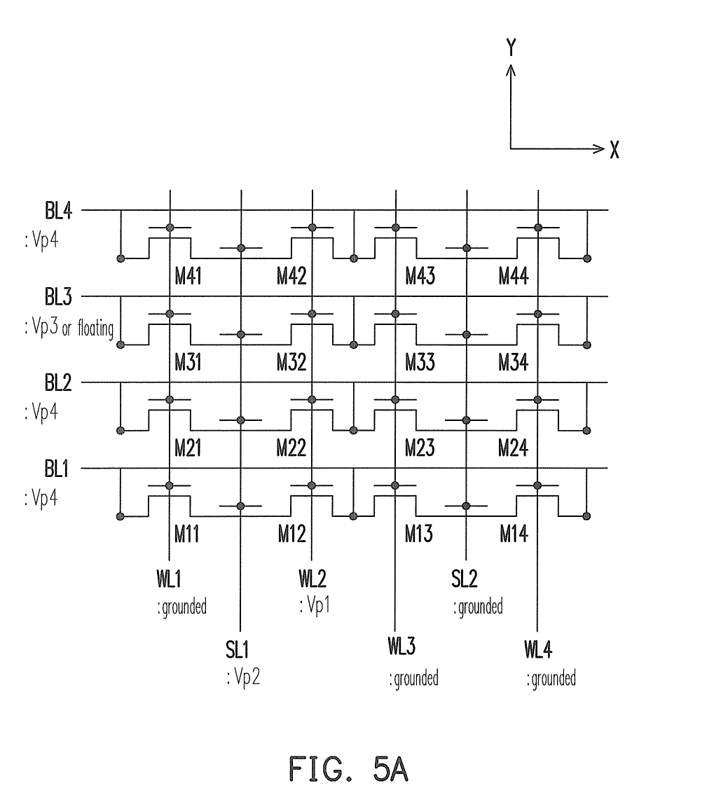

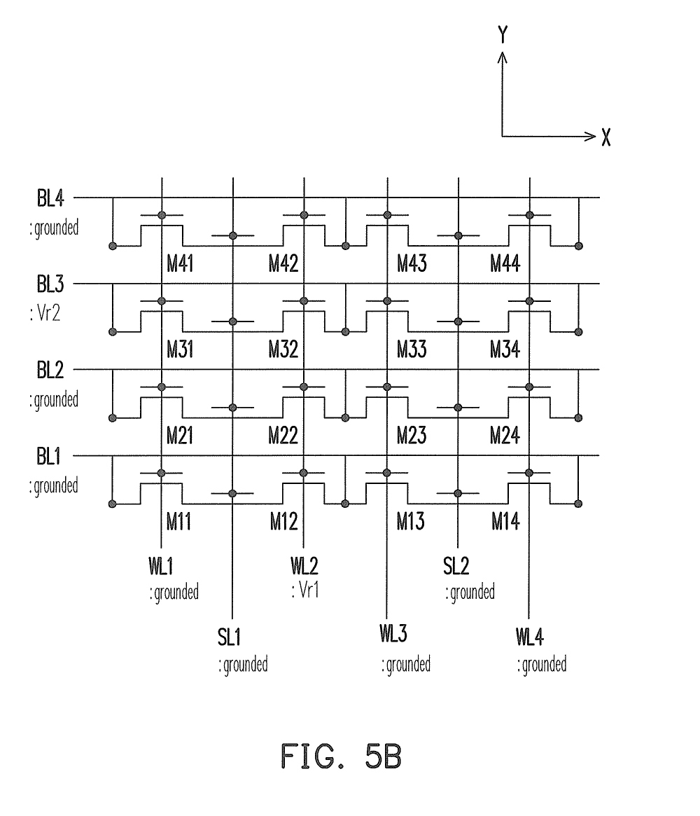

FIG. 5A is a schematic diagram showing a programming operation of a memory array according to one embodiment of the invention.

Referring to FIG. 5A, when a programming operation is performed to the selected memory cell M32, the voltage Vp1 is applied to the selected word line WL2 coupled to the selected memory cell M32, the voltage Vp2 is applied to the selected source line SL1 coupled to the selected memory cell M32, the voltage Vp3 is applied to the selected bit line BL3 coupled to the selected memory cell M32 or the selected bit line BL3 is floating. The voltage Vp1 is sufficient to turn on the channel of the transistor of the selected memory cell. The voltage Vp1 is, for instance, 3.3 V. A voltage difference between the voltage Vp2 and the voltage Vp3 is sufficient for the dielectric layer 112 to break down. The voltage difference is 6-9 V, for example. The voltage Vp2 is 6-9 V, for instance, while the voltage Vp3 is, for example, 0 V.

Moreover, when the selected memory cell M32 is being programmed, other unselected word lines WL1, WL3, WL4 and other unselected source line SL2 are grounded; other unselected bit lines BL1, BL2, BL4 are applied with a voltage Vp4. A voltage difference between the voltage Vp2 and the voltage Vp4 is insufficient for the dielectric layer 112 to break down. The voltage Vp4 is, for example, 6-9 V.

As shown in FIG. 5A, when the selected memory cell M32 is being programmed, the 3.3 V voltage applied to the selected word line WL2 turns on the channel of the transistor, such that the 0 V voltage applied to the selected bit line BL3 is conducted to the source region, and the voltage of the source region is maintained at about 0 V. At this point, a 6-9 V voltage is applied to the selected source line SL1. Therefore, a large voltage difference is generated between the selected source line SL1 and the source region. As a result, the dielectric layer breaks down and the memory cell M32 is programmed.

As for other unselected memory cells M12, M22, M42 sharing the word line WL2 and the source line SL1 with the selected memory cell M32, when the programming operation is performed, a 6-9 V voltage is applied the unselected bit lines BL1, BL2, BL4 coupled to these unselected memory cells M12, M22, M42, and the 6-9 V voltage of the unselected bit line BL3 is conducted to the source region. As a consequence, the selected source line SL1 and the source region have no voltage difference. Thus, the unselected memory cells M12, M22, M42 are prevented from being programmed.

As for other unselected memory cells M31, M33, M34 sharing the bit line BL3 with the selected memory cell M32, when the programming operation is performed, since the unselected word line WL1, WL3, WL4 coupled to these unselected memory cells M31, M33, M34 are grounded, the selected source line SL2 and the source region have no voltage difference. Therefore, the unselected memory cells M31, M33, M34 are not programmed.

Although the above-mentioned programming operation of the one time programmable memory is performed on a single memory cell in the memory array, the programming operation of the non-volatile memory of the invention can also be coded in units of byte, sector or block by controlling the various word lines and bit lines.

FIG. 5B is a schematic diagram showing a reading operation of a memory array according to one embodiment of the invention.

When the reading operation is performed, the voltage Vr1 is applied to the selected word line WL2 coupled to the selected memory cell M32, so that the selected source line SL1 coupled to the selected memory cell M32 is grounded. Also, the voltage Vr2 is applied to the selected bit line BL3 coupled to the selected memory cell M32 to read the selected memory cell M32. The voltage Vr1 is sufficient to turn on the channel of the transistor of the selected memory cell M32. The voltage Vr1 is, for example, 3.3 V. The voltage Vr2 is, for example, 1-4 V.

Then, a 3.3 V voltage, for example, is applied to the word line WL2 to turn on the channel of the transistor. When the dielectric layer breaks down for the transistor and the source line SL1 to be conducted, electrons are channeled away through the source line SL1. The voltage on the bit line BL3 is thus reduced. When the dielectric layer does not break down, the transistor and the electrode are not conducted; consequently, the electrons are not channeled away through the source line SL1. The voltage on the bit line BL3 is thus maintained at about 1-4 V. As a result, whether the digital data stored inside the memory cell is ‘1’ or ‘0’ can be determined by reading the voltage on the bit line.

In the operation mode of the one time programmable memory in the invention, digital data is determined according to whether the bit line and the source line are conducted, which is in turn determined by whether the dielectric layer breaks down or not.

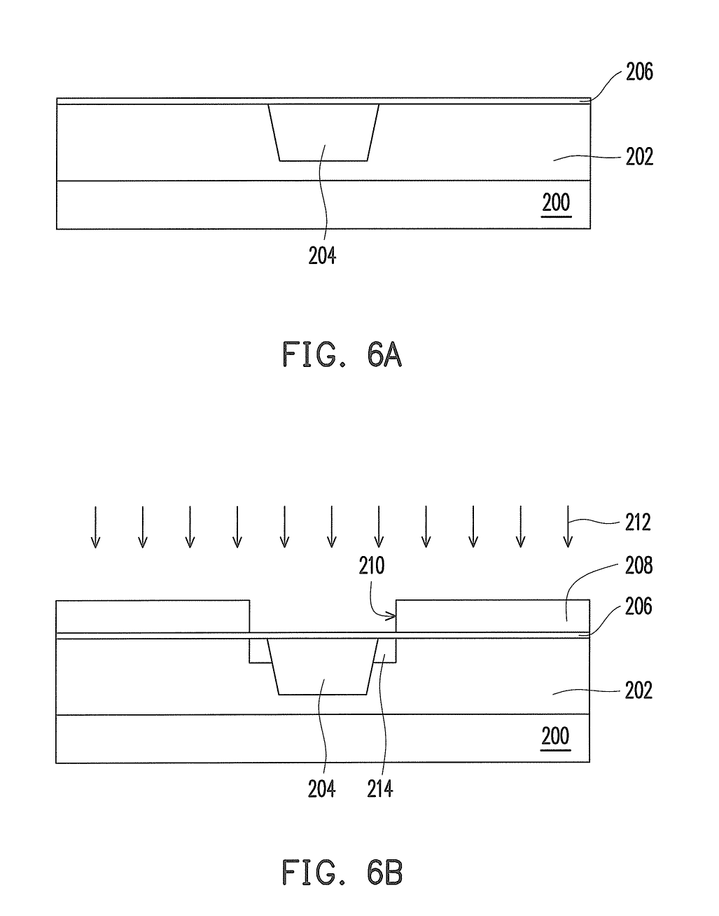

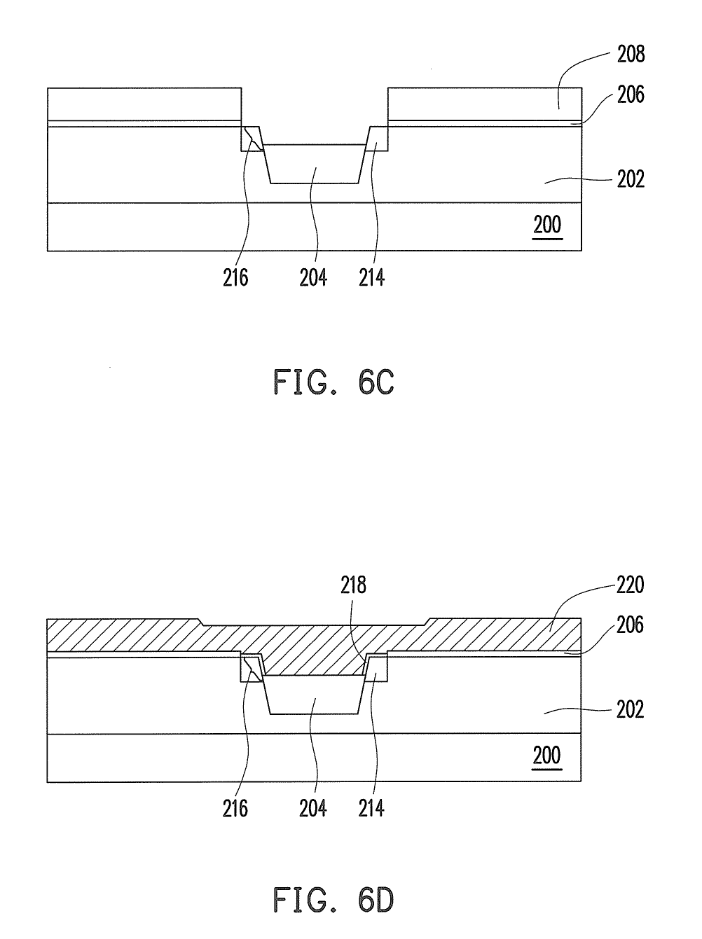

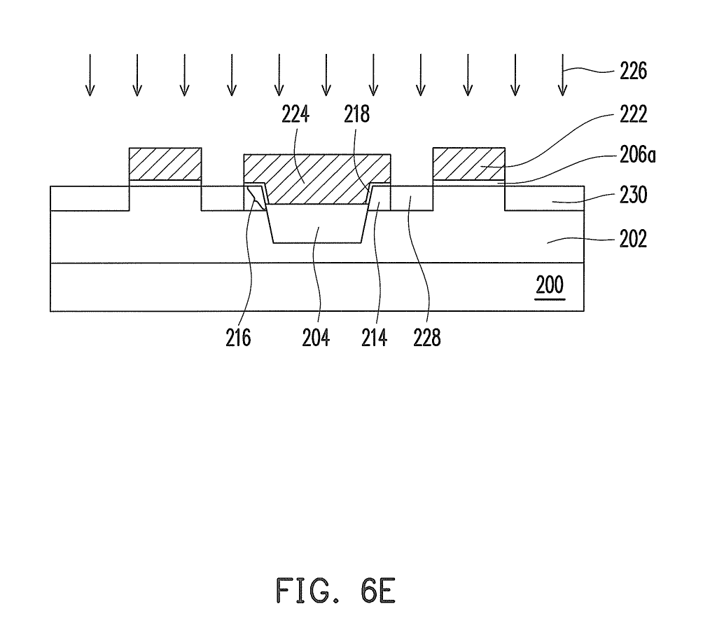

FIGS. 6A through 6E are schematic cross-sectional views showing the flowchart for fabricating a one time programmable memory of the invention.

As shown in FIG. 6A, a substrate 200 is provided. The substrate 200 is a silicon substrate, for example. The substrate 200 has a P-type well 202 and an isolation structure 204 formed thereon for defining an active region. For example, the P-type well 202 is formed by performing an ion implantation process. The isolation structure 204 is, for instance, a shallow trench isolation structure which can be fabricated using the conventional shallow trench isolation process.

Then, a dielectric layer 206 is formed on the substrate 200 sequentially. The material used for fabricating the dielectric layer 206 is, for example, silicon oxide, and the method for fabricating the same is, for instance, a thermal oxidation process or a chemical vapor deposition process.

Referring to FIG. 6B, a mask layer 208 having an opening 210 is formed on the substrate layer 200. The width of the opening 210 is greater than the width of a top portion of the isolation structure 204. The mask layer is fabricated using a photoresist material, for instance. A method of forming the mask layer 208 includes forming a photoresist material layer on the entire substrate 200 first. Later, an exposure process and a development process are performed to form the mask layer 208.

Thereafter, the mask layer 208 is used as a mask to perform an ion implantation step 212 for forming a doped region 214 in the substrate 200 around the isolation structure 204. The implanted dopant is an N-type dopant, for example. The doped region 214 is formed by, for example, an ion implantation process.

Referring to FIG. 6C, the mask layer 208 is applied as a mask to remove a portion of the dielectric layer 206 and a portion of the isolation structure 204, such that an upper surface of the isolation structure 204 is lower than a surface of the substrate 200 so as to expose the isolation structure 204 and a top edge corner region 216. A method used for removing a portion of the dielectric layer 206 and a portion of the isolation structure 204 is, for example, an etching process such as a dry etching process or a wet etching process.

Next, referring to FIG. 6D, the mask layer 208 is removed. A method of removing the mask layer 208 includes, for example, a wet photoresist stripping process or a dry photoresist stripping process. After the mask layer 208 is removed, a dielectric layer 218 is formed in the top edge corner region 216. The dielectric layer 218 is, for example, fabricated using silicon oxide, and a method of forming the dielectric layer 218 includes the CVD process or the thermal oxidation process, for example. The dielectric layer 218 has a thickness ranging from 26 Å to 46 Å. Obviously, the dielectric layer 218 can be fabricated using other dielectric materials. Through the selection of a suitable dielectric material and the formation of a dielectric layer with appropriate thickness, the breakdown voltage and device performance of the memory can be controlled.

Then, a conductive material layer 220 is formed on the substrate 200. The conductive material layer 220 is fabricated with doped polysilicon, for example. The conductive material layer 220 is formed, for example, by performing a chemical vapor deposition process with in-situ dopant implant or forming an undoped polysilicon layer over the substrate 200 in a chemical deposition process followed by performing an ion implant process.

Referring to FIG. 6E, the conductive material layer 220 and the dielectric layer 206 are patterned to form a conductive layer 224, a gate 222 and a gate dielectric layer 206a. The conductive material layer 220 and the dielectric layer 206 are patterned, for example, by performing photolithographic and etching processes. The conductive layer 224 is disposed on the isolation structure 204 and covers the top edge corner region 216. Then, a dopant implantation step 226 is performed to form a doped region 228 and a doped region 230 in the substrate 200 at opposite sides of the gate 222. The implanted dopant is an N-type dopant, for example. The doped region 214 is formed by, for example, an ion implantation process. The conductive layer 224, the dielectric layer 206, and the doped region 218 (the doped region 228) constitute the anti-fuse structure.

In the present embodiment, the doped region 218 and the doped region 228 are used as examples in different dopant implantation processes for illustration. Obviously, the doped region 218 and the doped region 228 can also be formed in the same dopant implantation process.

The method of fabricating the one time programmable memory of the invention is compatible with the conventional CMOS process. This process in the invention is also simple, so that the overall production cost can be reduced. Moreover, a portion of the dielectric layer 206 and a portion of the isolation structure 204 are removed, such that an upper surface of the isolation structure 204 is lower than a surface of the substrate 200 so as to expose the isolation structure 204 and the top edge corner region 216. Thus, electric charges can easily concentrate around the corner of the top edge corner region 216 to produce an electric discharge that breaks down the dielectric layer. Thus, the operation voltage is reduced.

In light of the foregoing, since the one time programmable memory of the invention have an anti-fuse structure, which is constituted by the doped region, the dielectric layer, and the conductive layer, the size of devices on the top edge corner region of the isolation structure can be reduced.

In addition, the anti-fuse structure is disposed in the top edge corner region. Thus, electric charges can easily concentrate around the top edge corner region to produce an electric discharge that breaks down the dielectric layer. The voltage for operating the dielectric layer is therefore reduced. In addition, the breakdown voltage and device performance of the memory can be controlled through a proper selection of the material and thickness of the dielectric layer.

The invention is directed to an operation method of a one time programmable memory. During the programming process, whether the dielectric layer breaks down or not can be utilized to provide the memory cell with the one time programming characteristic, and the stored data is non-volatile. During the reading process, the voltage change of a bit line resulted from whether the dielectric layer breaks down or not is utilized to interpret digital data.

The manufacturing method of the one time programmable memory in the invention utilizes a conventional CMOS process, such that devices have higher integration and the manufacturing cost thereof is reduced effectively.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A one time programmable memory having a memory cell disposed on a substrate, the memory cell comprising:
a gate, disposed on the substrate;
a gate dielectric layer, disposed between the substrate and the gate;
a first doped region and a second doped region, disposed in the substrate at opposite sides of the gate respectively;
an isolation structure, disposed in the substrate and adjacent to the first doped region, wherein an upper surface of the isolation structure is lower than a surface of the substrate so as to expose a top edge corner region;
a conductive layer, disposed on the isolation structure and covering the top edge corner region; and
a dielectric layer, disposed in the top edge corner region and located between the conductive layer and the first doped region, wherein the memory cell stores digital data depending on whether the dielectric layer breaks down or not.

2. The one time programmable memory as claimed in claim 1, wherein the first doped region is a drain region and the conductive layer is electrically connected to a bit line; and the second doped region is a source region and electrically connected to a source line.

3. The one time programmable memory as claimed in claim 1, wherein the first doped region is a source region and the conductive layer is electrically connected to a source line; and the second doped region is a drain region and electrically connected to a bit line.

4. The one time programmable memory as claimed in claim 1, wherein the first doped region comprises a third doped region and a fourth doped region, the third doped region is disposed between the isolation structure and the fourth doped region and located below the conductive layer.

5. The one time programmable memory as claimed in claim 1, further comprising:
a plurality of the memory cells arranged in a column/row to form an array, wherein two adjacent memory cells are disposed in mirror symmetry in a column direction;
a plurality of word lines, each connected to the gate of the memory cells in a same row respectively;
a plurality of source lines, each connected to the second doped region of the memory cells in the same row respectively; and
a plurality of bit lines, each connected to the conductive layer of the memory cells in the same column respectively.

6. The one time programmable memory as claimed in claim 1, further comprising:
a plurality of the memory cells arranged in a column/row to form an array, wherein two adjacent memory cells are disposed in minor symmetry manner in a column direction;
a plurality of word lines, each connected to the gate of the memory cells in a same row respectively;
a plurality of source lines, each connected to the conductive layer of the memory cells in the same row respectively; and
a plurality of bit lines, each connected to the second doped region of the memory cells in the same column respectively.

7. A manufacturing method of a one time programmable memory, comprising:
providing a substrate having an isolation structure formed therein;
forming a first dielectric layer on the substrate;
removing a portion of the first dielectric layer and a portion of the isolation structure, such that an upper surface of the isolation structure is lower than a surface of the substrate so as to expose a top edge corner region;
forming a second dielectric layer in the top edge corner region;
forming a gate and a conductive layer on the substrate, wherein the conductive layer is disposed on the isolation structure and covers the top edge corner region; and
forming a first doped region and a second doped region in the substrate at opposite sides of the gate, wherein the first doped region, the second dielectric layer, and the conductive layer constitute a fuse-structure.

8. The manufacturing method as claimed in claim 7, wherein the second dielectric layer is formed using a thermal oxidation.

9. The manufacturing method as claimed in claim 7, wherein before the step of removing a portion of the first dielectric layer and a portion of the isolation structure, the method further comprises forming a third doped region in the top edge corner region.

10. The manufacturing method as claimed in claim 7, wherein a method of forming the gate and the conductive layer on the substrate comprises:
forming a conductive material layer on the substrate; and
patterning the conductive material layer.

11. An operation method of a one time programmable memory, the one time programmable memory at least comprising: a plurality of memory cells arranged in a column/row to form an array, wherein two adjacent memory cells are disposed in mirror symmetry manner in a column direction, each memory cell comprising: a transistor having a first doped region and a second doped region, an isolation structure adjacent to the first doped region and exposing a top edge corner region, a conductive layer disposed on the isolation structure and covering the top edge corner region, and a dielectric layer disposed in the top edge corner region and located between the conductive layer and the first doped region; a plurality of word lines, each connected to the gate of the memory cells in a same row respectively; a plurality of source lines, each connected to the conductive layer of the memory cells in the same row respectively; a plurality of bit lines, each connected to the second doped region of the memory cells in the same column respectively, and the method comprising:
when performing a programming operation, applying a first voltage to a selected word line coupled to a selected memory cell, applying a second voltage to a selected source line coupled to the selected memory cell, applying a third voltage to a selected bit line coupled to the selected memory cell or floating the selected bit line, wherein the first voltage is sufficient to turn on a channel of the transistor of the selected memory cell, and a voltage difference between the second voltage and the third voltage is sufficient for the dielectric layer to break down.

12. The operation method as claimed in claim 11, wherein the first voltage is 3.3 Volts (V).

13. The operation method as claimed in claim 11, wherein the voltage difference is 6-9 V.

14. The operation method as claimed in claim 11, wherein the second voltage is 6-9 V and the third voltage is 0 V.

15. The operation method as claimed in claim 10, further comprising:
when performing the programming operation, applying a fourth voltage to other unselected bit lines, wherein a voltage difference between the second voltage and the fourth voltage is not sufficient for the dielectric layer to break down.

16. The operation method as claimed in claim 11, wherein the fourth voltage is 6-9 V.

17. The operation method as claimed in claim 10, further comprising:
when performing a reading operation, applying a fifth voltage to the selected bit line coupled to the selected memory cell, so that the selected source line coupled to the selected memory cell is grounded, applying a sixth voltage to the selected bit line coupled to the selected memory cell to read the selected memory cell, wherein the fifth voltage is sufficient to turn on the channel of the transistor of the selected memory cell.

18. The operation method as claimed in claim 17, wherein the fifth voltage is 3.3 V

19. The operation method as claimed in claim 17, wherein the sixth voltage is 1-4 V.

20. An operation method of a one time programmable memory, the one time programmable memory at least comprising: a plurality of memory cells arranged in a column/row to form an array, wherein two adjacent memory cells are disposed in mirror symmetry manner in a column direction, each memory cell comprising: a transistor having a first doped region and a second doped region, an isolation structure adjacent to the first doped region and exposing a top edge corner region, a conductive layer disposed on the isolation structure and covering the top edge corner region, and a dielectric layer disposed in the top edge corner region and located between the conductive layer and the first doped region; a plurality of word lines, each connected to the gates of the memory cells in a same row respectively; a plurality of source lines, each connected to the second doped region of the memory cells in the same row respectively; a plurality of bit lines, each connected to the conductive layer of the memory cells in the same column respectively, and the method comprising:
when performing a programming operation, applying a first voltage to a selected word line coupled to a selected memory cell, applying a second voltage to a selected bit line coupled to the selected memory cell, applying a third voltage to a selected source line coupled to the selected memory cell or floating the selected source line, wherein the first voltage is sufficient to turn on a channel of the transistor of the selected memory cell, and a voltage difference between the second voltage and the third voltage is sufficient for the dielectric layer to break down.

21. The operation method as claimed in claim 20, wherein the first voltage is 3.3 V

22. The operation method as claimed in claim 20, wherein the voltage difference is 6-9 V.

23. The operation method as claimed in claim 20, wherein the second voltage is 6-9 V and the third voltage is 0 V.

24. The operation method as claimed in claim 20, further comprising:
when performing a reading operation, applying a fourth voltage to the selected word line coupled to the selected memory cell, so that the selected source line coupled to the selected memory cell is grounded, applying a fifth voltage to the selected bit line coupled to the selected memory cell to read the selected memory cell, wherein the fourth voltage is sufficient to turn on the channel of the transistor of the selected memory cell.

25. The operation method as claimed in claim 20, wherein the fourth voltage is 3.3 V.

26. The operation method as claimed in claim 20, wherein the fifth voltage is 1-4 V.
